(19) United States
(12) Patent Application Publication
(10) Pub. No.: US 2024/0324414 A1
(43) Pub. Date: Sep. 26, 2024

(54) DISPLAY DEVICE AND METHOD OF MANUFACTURING THE DISPLAY DEVICE

(71) Applicant: Samsung Display Co., Ltd., Yongin-si (KR)

(72) Inventors: Inok Kim, Yongin-si (KR); Chansu Kim, Yongin-si (KR); Keunchan Oh, Yongin-si (KR); Gakseok Lee, Yongin-si (KR); Sanghun Lee, Yongin-si (KR); Soyun Lee, Yongin-si (KR); Jieun Jang, Yongin-si (KR); Changsoon Jang, Yongin-si (KR)

(73) Assignee: Samsung Display Co., Ltd., Yongin-si (KR)

(21) Appl. No.: 18/520,977

(22) Filed: Nov. 28, 2023

(30) Foreign Application Priority Data
Mar. 24, 2023 (KR) 10-2023-0039118
Mar. 29, 2023 (KR) 10-2023-0041497

(51) Int. Cl. H10K 59/80; H10K 59/12; H10K 59/35

(52) U.S. Cl. CPC H10K 59/877; H10K 59/1201; H10K 59/35

(57) ABSTRACT

A display device includes a first pixel, a third pixel, and a third pixel emitting light of different colors, light-emitting diodes corresponding to the first pixel, the second pixel, and the third pixel and emitting light of a same color, and a function layer disposed in a direction in which the light-emitting diodes emit light and including a first color conversion layer corresponding to a first emission area of the first pixel, a second color conversion layer corresponding to a second emission area of the second pixel, and a transmitting layer corresponding to a third emission area of the third pixel. The first color conversion layer includes first quantum dots, the second color conversion layer includes second quantum dots, and each of the first color conversion layer, the second color conversion layer, and the transmitting layer include a base resin in which a plurality of pores are defined.

### CROSS-REFERENCE TO RELATED APPLICATION(S)

This application claims priority to and the benefits of Korean Patent Application Nos. 10-2023-0039118, filed on Mar. 24, 2023 in the Korean Intellectual Property Office, and 10-2023-0041497, filed on Mar. 29, 2023, in the Korean Intellectual Property Office, the entire contents of which are herein incorporated by reference.

### BACKGROUND

### 1. Technical Field

Embodiments relate to a display device and a method of manufacturing the display device.

### 2. Description of the Related Art

Display devices display data in a visual manner. According to the development of various electronic devices such as mobile phones, personal digital assistants (PDAs), computers and, large-sized televisions, various kinds of display devices applicable thereto have been developed. For example, display devices widely used in the market include liquid crystal display devices including backlight units and organic light-emitting devices that emit light of different colors from center areas. Also, recently, display devices including quantum-dot color-conversion layers (QD-CCL) have been developed. Quantum dots are excited by incident light thereon and emit light having a wavelength greater than a wavelength of the incident light. Light in a short-wavelength band is mostly used as the incident light. Recently, as display devices have been variously used, numerous designs to improve the quality of display devices have been proposed.

### SUMMARY

Embodiments provide a display device having improved display quality and a method of manufacturing the display device. However, this is merely an example, and the scope of the disclosure is not limited thereto.

Additional aspects will be set forth in part in the description which follows and, in part, will be apparent from the description, or may be learned by practice of the embodiments of the disclosure.

According to an embodiment, a display device may include a first pixel, a second pixel, and a third pixel emitting light of different colors, light-emitting diodes that correspond to the first pixel, the second pixel, and the third pixel and that emit light of a same color, and a function layer disposed in a direction in which the light-emitting diodes emit light, the function layer including a first color conversion layer corresponding to a first emission area of the first pixel, a second color conversion layer corresponding to a second emission area of the second pixel, and a transmission layer corresponding to a third emission area of the third pixel. The first color conversion layer may include first quantum dots, the second color conversion layer may include second quantum dots, and each of the first color conversion layer, the second color conversion layer, and the transmitting layer may include a base resin in which a plurality of pores are defined.

In an embodiment, a size of each of the plurality of pores may be greater than a size of each of the first quantum dots, and the size of each of the plurality of pores may be greater than a size of each of the second quantum dots.

In an embodiment, each of the first color conversion layer, the second color conversion layer, and the transmitting layer may include scattering particles and low-refractive objects having a refractive index greater than about 1.0 and less than or equal to about 1.3.

In an embodiment, the display device may further include a color filter layer including a first color filter disposed corresponding to the first emission area, a second color filter disposed corresponding to the second emission area, and a third color filter disposed corresponding to the third emission area.

In an embodiment, the display device may further include a low-refractive layer disposed between the function layer and the color filter layer and having a refractive index less than a refractive index of the color filter layer.

In an embodiment, the low-refractive layer may have a refractive index less than a refractive index of the function layer.

In an embodiment, a difference between the refractive index of the low-refractive layer and the refractive index of the function layer may be greater than or equal to about 0.1 and less than or equal to about 0.6.

In an embodiment, each of the first color conversion layer, the second color conversion layer, and the transmitting layer may further include scattering particles and low-refractive objects having a refractive index greater than about 1.0 and less than or equal to about 1.3, and the low-refractive layer and the low-refractive objects may include a same material.

In an embodiment, each of the first color conversion layer, the second color conversion layer, and the transmitting layer may further include scattering particles and low-refractive objects having a refractive index greater than about 1.0 and less than or equal to about 1.3, and the low-refractive layer and the low-refractive objects may include a different material.

In an embodiment, the refractive index of the function layer may be equal to or greater than or equal to about 1.5 and less than or equal to about 1.7.

In an embodiment, a porosity of the first color conversion layer, a porosity of the second color conversion layer, and a porosity of the transmitting layer may be different from one another.

According to an embodiment, a display device may include an emission panel including a plurality of light-emitting diodes, a color panel disposed on the emission panel and including a first center area, a second center area, and a third center area overlapping the plurality of light-emitting diodes and that emit light having different colors. The color panel may include a function layer including a first color conversion layer corresponding to the first center area, a second color conversion layer corresponding to the second center area, and a transmitting layer corresponding to the third center area. The first color conversion layer may include first quantum dots, the second color conversion layer may include second quantum dots, and each of the first color conversion layer, the second color conversion layer, and the transmitting layer each include a base resin in which a plurality of pores are defined.

In an embodiment, a size of each of the plurality of pores may be greater than a size of each of the first quantum dots and a size of each of the second quantum dots.

In an embodiment, each of the first color conversion layer, the second color conversion layer, and the transmitting layer may include scattering particles and low-refractive objects having a refractive index greater than about 1.0 and less than or equal to about 1.3.

According to an embodiment, a method of manufacturing a display device may include forming, on a substrate, a bank layer in which a first opening, a second opening, and a third opening are defined, providing, in the first opening, a first material obtained by mixing a first base resin, porogen, and first quantum dots, providing in the second opening, a second material obtained by mixing a second base resin, porogen, and second quantum dots, providing, in the third opening, a third material obtained by mixing a third base resin and porogen, and forming, by heating the first material, the second material, and the third material, a function layer including a first color conversion layer, a second color conversion layer, and a transmitting layer each including a plurality of pores are defined.

In an embodiment, a size of the plurality of pores may be greater than a size of each of the first quantum dots, and the size of the plurality of pores is greater than a size of each of the second quantum dots.

In an embodiment, the first material, the second material, and the third material may further include low-refractive objects having a refractive index greater than about 1.0 and less than or equal to about 1.3.

In an embodiment, content ratios of porogen in the first material, the second material, and the third material may be different from one another.

In an embodiment, the refractive index of the function layer may be greater than or equal to about 1.4 and less than or equal to about 1.7.

In an embodiment, before the forming of the bank layer, the method may further include forming, on the substrate, a color filter layer including a first color filter, a second color filter, and a third color filter, and forming, on the color filter layer, a low-refractive layer having a refractive index less than a refractive index of the color filter layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display device according to an embodiment of the disclosure;

FIG. 2 is a cross-sectional view schematically illustrating a display device according to an embodiment of the disclosure;

FIG. 3 is a schematic diagram of an equivalent circuit of a pixel circuit included in a display device according to an embodiment of the disclosure;

FIG. 4 is a cross-sectional view schematically illustrating a portion of the display device shown in FIG. 1;

FIG. 5 schematically illustrates an enlarged image of a function layer according to an embodiment of the disclosure;

FIG. 6 schematically illustrates an enlarged image of a function layer according to another embodiment of the disclosure; and

FIG. 7 is a flowchart showing a method of manufacturing a display device according to an embodiment of the disclosure.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Rather, the embodiments are merely described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

As used herein, the terms ‘first’, ‘second’ are only used to distinguish one element from another, not by way of limitation.

As used herein, the singular forms are intended to encompass the plural forms as well, unless the context clearly indicates otherwise.

It will be further understood that the terms “comprise,” “comprising,” “include,” “including,” “have,” “having,” and the like, when used herein, specify the presence of stated features and/or elements, but do not preclude the presence or addition of one or more other features and/or elements.

In the following embodiments, when a portion such as a film, an area, or a component is on or above another portion, the portion may be directly on the other portion, or other films, areas, or components may be located therebetween.

In the drawings, the sizes of elements may be exaggerated or reduced for convenience of description. For example, since the size and thickness of each element is arbitrarily shown in the drawings for convenience of description, the disclosure is not necessarily limited to those illustrated.

In the following embodiments, when it is referred that a wiring “extends in a first direction or a second direction”, the expression includes that the wiring extends in a zigzag shape or a curved shape in the first direction or the second direction, as well as linear extension.

In the following embodiments, “in a top-plan view” indicates that a subject is viewed from top, and “in a cross-sectional view” indicates that a cross-section obtained by cutting the subject in a vertical direction is viewed from a side.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

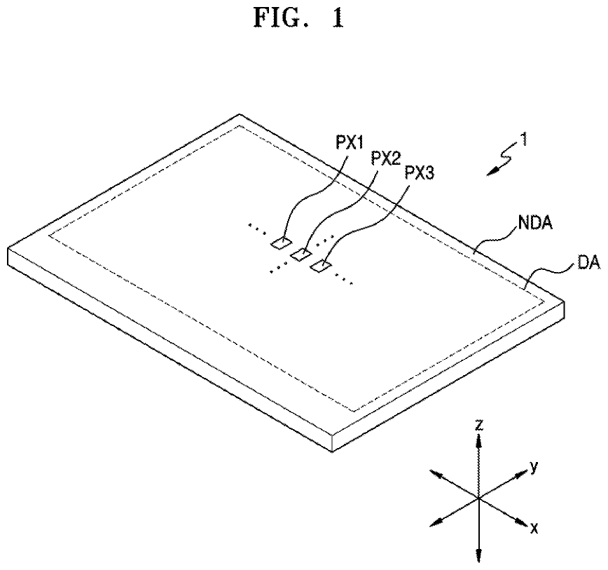

FIG. 1 is a perspective view schematically illustrating a display device 1 according to an embodiment of the disclosure.

Referring to FIG. 1, the display device 1 may include a display device 1, in which images may be implemented, and a non-display area in which images may not be implemented. The display device 1 may provide images through an array of pixels two-dimensionally arranged on a x-y plane of the display area DA.

In an embodiment, the pixels may include a first pixel PX1, a second pixel PX2, and a third pixel PX3. The first pixel PX1, the second pixel PX2, and the third pixels PX3 are areas from which light having different colors may be emitted, and the display device 1 may provide images using light emitted from the pixels.

The non-display area NDA may include an area that does not provide images, and may generally surround the display area DA. A driver or a main voltage line that provides electrical signals or power to pixel circuits may be arranged in the non-display area NDA. The non-display area NDA may include a pad that is an area to which electronic devices or a printed circuit board may be electrically connected.

The display area DA may have a polygon shape, including a square, as shown in FIG. 1. For example, the display area DA may have a rectangular shape in which a horizontal length is greater than a vertical length, a rectangular shape in which a horizontal length is less than a vertical length, or a square shape. In other embodiments, the display area DA may include a polygon such as a circle, an oval, a triangle, or a pentagon. Although the display device 1 shown in FIG. 1 is illustrated as a flat display device having a flat shape, the display device 1 may be implemented as various shapes, e.g., a flexible, foldable, and/or rollable display device.

In an embodiment, the display device 1 may include an organic light-emitting display device. In other embodiments, the display device 1 may include an inorganic light-emitting display device or a quantum-dot light-emitting display device. For example, an emission layer of a display element included in the display device 1 may include an organic material, may include an inorganic material, may include quantum dots, may include an organic material and quantum dots, may include an inorganic material and quantum dots, or may include an organic material, an inorganic material, and quantum dots. Hereinafter, for convenience of explanation, a case in which the display device 1 includes an organic light-emitting device will be described in detail.

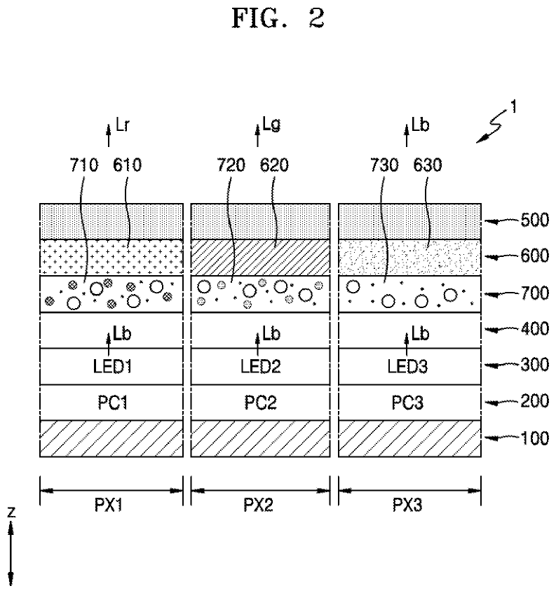

FIG. 2 is a cross-sectional view schematically illustrating the display device 1 according to an embodiment of the disclosure.

Referring to FIG. 2, the display device 1 may include a first substrate 100, a circuit layer 200, a light-emitting diode layer 300, an encapsulation layer 400, a function layer 700, a color filter layer 600, and a light-transmitting base layer 500. The first substrate 100 may be referred to as a bottom substrate.

The display device 1 may include a first pixel PX1, a second pixel PX2, and a third pixel PX3. The first pixel PX1, the second pixel PX2, and the third pixel PX3 may include pixels that emit light having different colors, respectively. For example, the first pixel PX1 may emit first color light Lr, the second pixel PX2 may emit second color light Lg, and the third pixel PX3 may emit third color light Lb. In an embodiment, the first color light Lr may include red light, the second color light Lg may include green light, and the third color light Lb may include blue light.

The circuit layer 200 may be disposed on the first substrate 100. The circuit layer 200 may include a first pixel circuit PC1, a second pixel circuit PC2, and a third pixel circuit PC3, which may each include a thin-film transistor and/or a capacitor. The first pixel circuit PC1, the second pixel circuit PC2, and the third pixel circuit PC3 may be respectively connected to a first light-emitting diode LED1, a second light-emitting diode LED2, and a third light-emitting diode LED3 of the light-emitting diode layer 300.

The first light-emitting diode LED1, the second light-emitting diode LED2, and the third light-emitting diode LED3 may include organic light-emitting diodes including an organic material. According to another embodiment, the first light-emitting diode LED1, the second light-emitting diode LED2, and the third light-emitting diode LED3 may include inorganic light-emitting diodes including an inorganic material. An inorganic light-emitting diode may include a p-n junction diode including materials based on an inorganic semiconductor. In case that a voltage in a positive direction is applied to the p-n junction diode, holes and electrons are injected, and light having certain colors may be emitted by converting energy, which is generated by recombination of the holes and electrons, into light energy. The aforementioned inorganic light-emitting diode may have a width of from several to hundreds of micrometers or from several to hundreds of nanometers. In some embodiments, the first light-emitting diode LED1, the second light-emitting diode LED2, and the third light-emitting diode LED3 may include light-emitting diodes including quantum dots. As described above, emission layers of the first light-emitting diode LED1, the second light-emitting diode LED2, and the third light-emitting diode LED3 may include an organic material, may include an inorganic material, may include quantum dots, may include an organic material and quantum dots, or may include an inorganic material and quantum dots.

The first light-emitting diode LED1, the second light-emitting diode LED2, and the third light-emitting diode LED3 may emit light having a same color. For example, the light (e.g., blue light Lb) emitted from the first light-emitting diode LED1, the second light-emitting diode LED2, and the third light-emitting diode LED3 may penetrate the function layer 700 via the encapsulation layer 400 on the light-emitting diode layer 300. However, the disclosure is not limited thereto. According to another embodiment, the first light-emitting diode LED1, the second light-emitting diode LED2, and the third light-emitting diode LED3 may emit light having different colors, respectively.

The function layer 700 may include optical layers that transmit the light (e.g., the blue light Lb) emitted from the light-emitting diode layer 300 with or without color conversion. For example, the function layer 700 may include color conversion layers, which convert the light (e.g., the blue light Lb) emitted from the light-emitting diode layer 300 into light having another color, and a transmitting layer that transmits the light (e.g., the blue light Lb) emitted from the light-emitting diode layer 300 without color conversion. The function layer 700 may include a first color conversion layer 710 corresponding to the first pixel PX1, a second color conversion layer 720 corresponding to the second pixel P2, and a transmitting layer 730 corresponding to the third pixel PX3. According to an embodiment, the first color conversion layer 710 may convert the blue light into red light, and the second color conversion layer 720 may convert the blue light Lb into green light Lg. The transmitting layer 730 may transmit the blue light Lb without color conversion.

The color filter layer 600 may be disposed on the function layer 700. The color filter layer 600 may include a first color filter 610, a second color filter 620, and a third color filter 630 having different colors. According to an embodiment, the first color filter 610 may include a red color filter, the second color filter 620 may include a green color filter, and the third color filter 630 may include a blue color filter.

Color purity of the light that has been color-converted or transmitted through the function layer 700 may be improved as the light penetrates the first color filter 610, the second color filter 620, and the third color filter 630. The color filter layer 600 may prevent or minimize reflection of external light (e.g., light incident to the display device 1 from the outside of the display device 1) and recognition of the light by the user.

The light-transmitting base layer 500 may be disposed on the color filter layer 600. The light-transmitting base layer 500 may include glass or a light-transmitting organic material. For example, the light-transmitting base layer 500 may include a light-transmitting organic material such as an acryl-based resin.

According to an embodiment, the light-transmitting base layer 500 may include a substrate and may be referred to as a second substrate. According to an embodiment, after the color filter layer 600 and the function layer 700 are formed on the light-transmitting base layer 500, the function layer 700 may be bonded to the encapsulation layer 400 in a manner of facing the encapsulation layer 400.

According to another embodiment, after the function layer 700 and the color filter layer 600 are sequentially formed on the encapsulation layer 400, the light-transmitting base layer 500 may be formed by being directly coated and cured on the color filter layer 600. According to some embodiments, other optical films, e.g., an anti-reflection (AR) film, may be disposed on the light-transmitting base layer 500.

The display device 1 having the aforementioned structure may include an electronic device by which videos or still images may be displayed (e.g., televisions, billboard charts, screens for theaters, monitors, tablet PCs, and notebook computers).

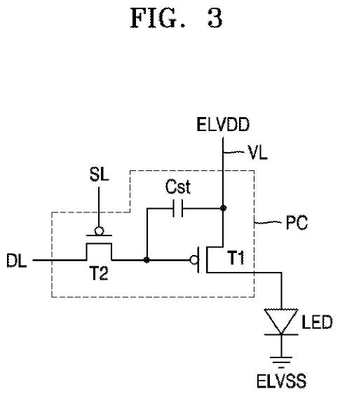

FIG. 3 is a schematic diagram of an equivalent circuit of a pixel circuit PC included in the display device 1 according to an embodiment of the disclosure.

Referring to FIG. 3, the pixel circuit PC may include thin-film transistors (TFT) and a storage capacitor Cst, and may be electrically connected to a light-emitting diode LED, e.g., a light-emitting element or the light-emitting diode layer 300 (see FIG. 2). According to an embodiment, the pixel circuit PC may include a driving thin-film transistor T1, a switching thin-film transistor T2, and a storage capacitor Cst.

The switching thin-film transistor T2 may be connected to a scan line SL and a data line DL, and may deliver a data signal or data voltage input from the data line DL to the driving thin-film transistor T1, based on a scan signal or switching voltage input from the scan line SL. The storage capacitor Cst may be connected to the switching thin-film transistor T2 and a driving voltage line VL, and may store a voltage corresponding to a difference between a voltage received from the switching thin-film transistor T2 and a first power voltage ELVDD provided to the driving voltage line VL.

The driving thin-film transistor T1 may be connected to the driving voltage line VL and the storage capacitor Cst, and may control a driving current flowing from the driving voltage line VL to the light-emitting diode LED, to correspond to a voltage of the voltage stored in the storage capacitor Cst. A counter electrode (e.g., a cathode) of the light-emitting diode LED may receive a second power voltage ELVSS. The light-emitting diode LED may emit light having certain luminance in response to the driving current.

Although a case is shown in which the pixel circuit PC includes two thin-film transistors and one storage capacitor, the disclosure is not limited thereto. For example, the pixel circuit PC may include three or more thin-film transistors and/or two or more storage capacitors. According to an embodiment, the pixel circuit PC may also include seven thin-film transistors and one storage capacitor. The numbers of thin-film transistors and storage capacitors may be variously modified according to the design of the pixel circuit PC. However, for convenience of explanation, a case in which the pixel circuit PC includes two thin-film transistors and one storage capacitor will be described hereinafter.

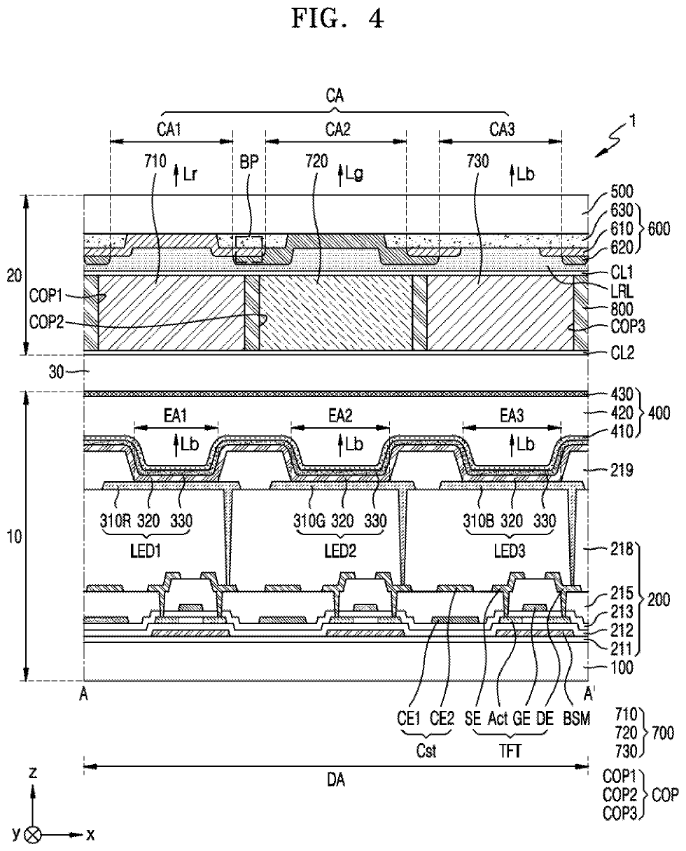

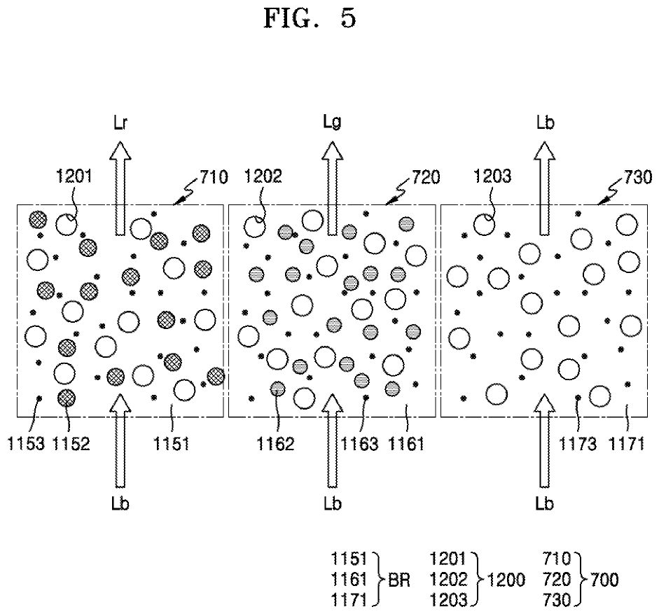

FIG. 4 is a cross-sectional view schematically illustrating a portion of the display device 1 shown in FIG. 1. FIG. 5 schematically illustrates an enlarged image of the function layer 700 according to an embodiment of the disclosure.

Referring to FIGS. 4 and 5, the display device 1 may include the first pixel PX1, the second pixel PX2, and the third pixel PX3, and the first pixel PX1 may implement red light Lr, the second pixel PX2 may implement green light Lg, and the third pixel PX3 may implement blue light Lb. The function layer 700 of the display device 1 may include a base resin BR in which pores 1200 are defined.

In an embodiment, the display device 1 may include an emission panel 10 and a color panel 20. In this case, the display device 1 may include a combination of the emission panel 10 and the color panel 20 that have been separately formed. However, the disclosure is not limited thereto. In another embodiment, the display device 1 may have a structure in which the first substrate 100, the circuit layer 200, the light-emitting diode layer 300, the encapsulation layer 400, the function layer 700, the color filter layer 600, and the light-transmitting base layer 500 are sequentially formed.

In an embodiment, the display device 1 may further include a filler layer 30 disposed between the emission panel 10 and the color panel 20. However, the disclosure is not limited thereto. In other embodiments, the filler layer 30 may be omitted. In an embodiment, the emission panel 10, the filler layer 30, and the color panel 20 may be stacked on each other in a thickness direction (e.g., a z direction). In an embodiment, the filler layer 30 may be disposed between the encapsulation layer 400 and the function layer 700.

The filler layer 30 may have a buffering function against external pressure and the like. The filler layer 30 may include an organic material such as methyl silicon, phenyl silicon, polyimide, and/or the like. However, the filler layer 30 is not limited thereto and may also include a urethane-based resin, an epoxy-based resin, and/or an acryl-based resin, i.e., organic sealants, silicon, i.e., an inorganic sealant, and/or the like.

The emission panel 10 may include the first substrate 100, the circuit layer 200 on the first substrate 100, the first light-emitting diode LED1, the second light-emitting diode LED2, and the third light-emitting diode LED3, to which the pixel circuits PC of the circuit layer 200 are electrically connected, and the encapsulation layer 400.

The circuit layer 200 may include pixel circuits respectively corresponding to the first pixel PX1, the second pixel PX2, and the third pixel PX3, and the pixel circuits may each include the thin-film transistors TFT and the storage capacitor Cst described above with reference to FIG. 3. For example, the thin-film transistor TFT may include the driving thin-film transistor T1 (see FIG. 3).

Hereinafter, a stack structure of the emission panel 10 will be described in detail.

The first substrate 100 may include glass material, ceramic material, a metal material, and/or a material that is flexible or bendable. In case that the first substrate 100 is flexible or bendable, the first substrate 100 may include a high-molecular resin such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The first substrate 100 may include a single-layer structure or multiple-layer structure including the material, and the multiple-layer structure may further include an inorganic layer. According to an embodiment, the first substrate 100 may have a structure including an organic material/an inorganic material/an organic material.

The circuit layer 200 may be disposed on the first substrate 100. The circuit layer 200 may include the thin-film transistors TFT and the storage capacitor Cst. In an embodiment, the circuit layer 200 may further include a first buffer layer 211, a second buffer layer 212, an interlayer insulating layer 215, and a planarization layer 218.

The first buffer layer 211 may be disposed on the first substrate 100. The first buffer layer 211 may reduce or block permeation of impurities, moisture or external air from the bottom of the first substrate 100, and may provide a planar surface on the first substrate 100. The first buffer layer 211 may include an inorganic insulating material, e.g., silicon oxide, silicon oxynitride, and/or silicon nitride, and may include a single-layer structure or multiple-layer structure including the aforementioned materials.

A barrier layer (not shown) may be further included in the display device 1, between the first substrate 100 and the first buffer layer 211. The barrier layer may prevent or minimize permeation of impurities from the first substrate 100 and the like into a semiconductor layer Act. The barrier layer may include an inorganic material such as an oxide or a nitride, an organic material, or an organic-inorganic complex, and may include a single-layer structure or multiple-layer structure including organic materials and inorganic materials.

A bias electrode BSM to correspond to the thin-film transistor TFT may be disposed on the first buffer layer 211. In an embodiment, a voltage may be applied to the bias electrode BSM. The bias electrode BSM may prevent the external light from approaching the semiconductor layer Act. Accordingly, features of the thin-film transistors TFT may be stabilized. The bias electrode may be omitted in other embodiments.

The second buffer layer 212 may be disposed on the first buffer layer 211. In an embodiment, the second buffer layer 212 may be disposed on the bias electrode BSM. The second buffer layer 212 may include an inorganic insulating material, e.g., silicon oxide, silicon oxynitride, and/or silicon nitride, and may include a single-layer structure or multiple-layer structure including the aforementioned materials.

The thin-film transistor TFT may be disposed over the first buffer layer 211. The thin-film transistor TFT may be disposed on the second buffer layer 212. The thin-film transistor TFT may include the semiconductor layer Act, a gate electrode GE, a source electrode SE, and a drain electrode DE. The thin-film transistor TFT may be connected to the first light-emitting diode LED1, the second light-emitting diode LED2, and the third light-emitting diode LED3 and may drive the first light-emitting diode LED1, the second light-emitting diode LED2, and the third light-emitting diode LED3.

The semiconductor layer Act may be disposed on the second buffer layer 212. The semiconductor layer Act may include, for example, amorphous silicon or polysilicon. According to another embodiment, the semiconductor layer Act may include an oxide of at least one material selected from a group including indium (In), gallium (Ga), tin (Sn), zirconium (Zr), vanadium (V), hafnium (Hf), cadmium (Cd), germanium (Ge), chromium (Cr), titanium (Ti), aluminum (AI), cesium (Cs), cerium (Ce), and zinc (Zn). In some embodiments, the semiconductor layer Act may include a Zn oxide-base material, i.e., Zn oxide, In—Zn oxide, and Ga—In—Zn oxide. In another embodiment, the semiconductor layer Act may include an In—Ga—Zn—O (IGZO) semiconductor, an In—Sn—Zn—O (ITZO) semiconductor, or an In—Ga—Sn—Zn—O (IGTZO) semiconductor, including a metal such as In, Ga, and Sn in zinc oxide. The semiconductor layer Act may include a channel area; and a source area and a drain area arranged at two sides of the channel area.

To secure insulation between the semiconductor layer Act and the gate electrode GE, a gate insulating layer 213 may be disposed between the semiconductor layer Act and the gate electrode GE. The gate insulating layer 213 may include an inorganic material, e.g., silicon oxide, silicon nitride, and/or silicon oxynitride.

The gate electrode GE may be disposed on the semiconductor layer Act having the gate insulating layer 213 therebetween. The gate electrode GE may at least partially overlap the semiconductor layer Act. The gate electrode GE may include, for example, molybdenum (Mo), Al, copper (Cu), Ti, and/or the like. The gate electrode GE may include a single layer or multiple layers. For example, the gate electrode GE may include a single layer including Mo.

The storage capacitor Cst may be disposed on the gate insulating layer 213. The storage capacitor Cst may include a first electrode CE1 and a second electrode CE2. The second electrode CE2 of the storage capacitor Cst may overlap the first electrode CE1 having the interlayer insulating layer 215 therebetween, and may construct the storage capacitor Cst. In this case, the interlayer insulating layer 215 may function as a dielectric layer of the storage capacitor Cst. The first electrode CE1 of the storage capacitor Cst may be arranged on a same layer as that of the gate electrode GE. The first electrode CE1 may include a same material as a material of the gate electrode GE. The first electrode CE1 of the storage capacitor Cst may be arranged on a same layer as that of the gate electrode GE.

Although FIG. 4 illustrates that the gate electrode GE of the thin-film transistor TFT and the first electrode CE1 of the storage capacitor Cst are separately arranged, the storage capacitor Cst may overlap the thin-film transistor TFT. In this case, the gate electrode GE of the thin-film transistor TFT may function as the first electrode CE1 of the storage capacitor Cst.

The interlayer insulating layer 215 may be disposed on the gate electrode GE and the storage capacitor Cst. The interlayer insulating layer 215 may cover the gate electrode GE and the storage capacitor Cst. The interlayer insulating layer 215 may include, for example, silicon oxide, silicon nitride, silicon oxynitride, aluminum oxide, titanium oxide, tantalum oxide, hafnium oxide, zinc oxide, and/or the like.

The second electrode CE2, the source electrode SE, and the drain electrode DE may be disposed on the interlayer insulating layer 215. The second electrode CE2, the source electrode SE, and the drain electrode DE may each include a conductive material including Mo, Al, Cu, Ti, and/or the like, and may include multiple-layers or a single layer including the aforementioned materials. For example, the second electrode CE2, the source electrode SE2, and the drain electrode DE may each have a multiple-layer structure including Ti/Al/Ti. The source electrode SE and the drain electrode DE may contact the source area or the drain area of the semiconductor layer Act through contact holes.

The planarization layer 218 may be disposed on the second electrode CE2, the source electrode SE, and the drain electrode DE. The planarization layer 218 may include a single layer or multiple layers of a film including organic materials, and may provide a planarized top surface. The planarization layer 218 may include, for example, a general-purpose polymer such as benzocyclobutene (BCB), polyimide, hexamethyldisiloxane, polymethylmethacrylate (PMMA), and polystyrene (PS), a polymer derivative having a phenolic group, an acryl-based polymer, an imide-based polymer, an arylether-based polymer, an amide-based polymer, a fluoride-based polymer, a p-xylene-based polymer, a vinylalcohol-based polymer, and blends thereof.

The first light-emitting diode LED1, the second light-emitting diode LED2, and the third light-emitting diode LED3 may be disposed on the circuit layer 200. The first light-emitting diode LED1, the second light-emitting diode LED2, and the third light-emitting diode LED3 may be disposed on the planarization layer 218. The first light-emitting diode LED1, the second light-emitting diode LED2, and the third light-emitting diode LED3 may include a first pixel electrode 310R, a second pixel electrode 310G, and a third pixel electrode 310B, respectively. In an embodiment, the first light-emitting diode LED1, the second light-emitting diode LED2, and the third light-emitting diode LED3 may include an emission layer 320 and a counter electrode 330 in common.

The first pixel electrode 310R, the second pixel electrode 310G, and the third pixel electrode 310B may each include a (semi) transparent electrode or a reflective electrode. In an embodiment, the first pixel electrode 310R, the second pixel electrode 310G, and the third pixel electrode 310B may each include a reflective layer including Ag, Mg, Al, Pt, Pd, Au, Ni, Nd, Ir, Cr, and compounds thereof, and a transparent or (semi) transparent electrode layer formed on the reflective layer. The transparent or (semi) transparent electrode layer may include at least one material selected from among a group including indium tin oxide (ITO), indium zinc oxide (IZO), zinc oxide, indium oxide, indium gallium oxide (IGO), and aluminum zinc oxide (AZO). In an embodiment, the first pixel electrode 310R, the second pixel electrode 310G, and the third pixel electrode 310B may be provided in the form of ITO/Ag/ITO.

An upper insulating layer 219 may be disposed on the planarization layer 218. The upper insulating layer 219 may include openings respectively exposing center portions of the first pixel electrode 310R, the second pixel electrode 310G, and the third pixel electrode 310B. The upper insulating layer 219 may cover edges of the first pixel electrode 310R, the second pixel electrode 310G, and the third pixel electrode 310B. The upper insulating layer 219 may increase a distance between rims of the first pixel electrode 310R, the second pixel electrode 310G, and the third pixel electrode 310B and the counter electrode 330 on the first pixel electrode 310R, the second pixel electrode 310G, and the third pixel electrode 310B, to thereby prevent occurrence of arcs and the like at the rims of the first pixel electrode 310R, the second pixel electrode 310G, and the third pixel electrode 310B.

The upper insulating layer 219 may be formed of, for example, at least one or more organic insulating materials selected from among a group including polyimide, polyamide, an acryl resin, BCB, and a phenol resin, and may be formed in a spin coating method or the like.

The emission layer 320 of each of the first light-emitting diode LED1, the second light-emitting diode LED2, and the third light-emitting diode LED3 may include an organic material including a fluorescent or phosphorescence material emitting green, red, blue, or white light. The emission layer 320 may include a low-molecular organic material or a high-molecular organic material, and a function layer such as a hole transport layer (HTL), a hole injection layer (HIL), an electron transport layer (ETL), and an electro injection layer (EIL) may be selectively further disposed under/above the emission layer 320.

Although FIG. 4 illustrates that the emission layer 320 is integrally formed over the first pixel electrode 310R, the second pixel electrode 310G, and the third pixel electrode 310B, the emission layer 320 is not limited thereto and may be variously modified, for example, may be arranged to correspond to each of the first pixel electrode 310R, the second pixel electrode 310G, and the third pixel electrode 310B.

In an embodiment, the emission layer 320 may include a first color emission layer. The first color emission layer may be integral over the first pixel electrode 310R, the second pixel electrode 310G, and the third pixel electrode 310B, and in an embodiment, may be patterned to correspond to each of the first pixel electrode 310R, the second pixel electrode 310G, and the third pixel electrode 310B. The first color emission layer may emit light in a first wavelength band, e.g., blue light. In an embodiment, the emission layer 320 may emit light in a wavelength of from about 450 nm to about 495 nm.

The counter electrode 330 may be disposed on the emission layer 320 to correspond to the first pixel electrode 310R, the second pixel electrode 310G, and the third pixel electrode 310B. The counter electrode 330 may be integrally formed for multiple organic light-emitting diodes. In an embodiment, the counter electrode 330 may include a transparent or a (semi) transparent electrode, and may include a metal thin-film having a small work function including Li, Ca, LiF/Ca, LiF/AI, AI, Ag, Mg, and compounds thereof. A transparent conductive oxide (TCO) layer including ITO, IZO, ZnO, In₂O₃, or the like on the metal thin-film.

In an embodiment, a light-emitting diode LED, e.g., each of the first light-emitting diode LED1, the second light-emitting diode LED2, and the third light-emitting diode LED3 may include multiple emission layers 320 sequentially stacked on each other. For example, the first light-emitting diode LED1, the second light-emitting diode LED2, and the third light-emitting diode LED3 may each include a first emission layer and a second emission layer sequentially stacked on each other. A negative-charge generating layer and a positive-charge generating layer may be disposed on the emission layer 320 adjacent to each other. For example, the negative-charge generating layer and the positive-charge generating layer may be disposed between the first emission layer and the second emission layer. In this case, in the light-emitting diode LED, the pixel electrode, the first emission layer, the negative-charge generating layer, the positive-charge generating layer, the second emission layer, and the counter electrode 330 may be sequentially stacked on each other. For example, the first pixel electrode 310R, the first emission layer, the negative-charge generating layer, the positive-charge generating layer, the second emission layer, and the counter electrode 330 may be sequentially stacked on each other in the first light-emitting diode LED1. For example, the negative-charge generating layer may provide electrons. The negative-charge generating layer may include an n-type charge generating layer. The negative-charge generating layer may include a host and a dopant. The host may include an organic material. The dopant may include a metal material. The positive-charge generating layer may include a p-type charge generating layer. The positive-charge generating layer may provide holes. The positive-charge generating layer may include the host and the dopant. The host may include an organic material. The dopant may include a metal material.

A first emission area EA1, a second emission area EA2, and a third emission area EA3 may correspond to the first pixel PX1, the second pixel PX2, and the third pixel PX3, respectively. The first emission area EA1, the second emission area EA2, and the third emission area EA3 may respectively include areas in which light generated in the first light-emitting diode LED1, the second light-emitting diode LED2, and the third light-emitting diode LED3 is emitted to the outside. In an embodiment, the first emission area EA1 may be defined as a portion of the first pixel electrode 310R exposed by an opening of the upper insulating layer 219. In an embodiment, the second emission area EA2 may be defined as a portion of the second emission area EA2 exposed by an opening of the upper insulating layer 219. In an embodiment, the third emission area EA3 may be defined as a portion of the third emission area EA3 exposed by an opening of the upper insulating layer 219.

The first emission area EA1, the second emission area EA2, and the third emission area EA3 may be apart from one another. In the display area DA, areas except the first emission area EA1, the second emission area EA2, and the third emission area EA3 may include non-emission areas. The first emission area EA1, the second emission area EA2, and the third emission area EA3 may be distinguished from one another by the non-emission area.

A spacer (not shown), which is for preventing a mask from being stamped, may be further included on the upper insulating layer 219. In an embodiment, the spacer may be integrally formed with the upper insulating layer 219. For example, the spacer and the upper insulating layer 219 may be simultaneously formed in a same process, for example, a halftone mask process.

As the first light-emitting diode LED1, the second light-emitting diode LED2, and the third light-emitting diode LED3 may be damaged due to external moisture or oxygen, they may be covered with the encapsulation layer 400 for protection. The encapsulation layer 400 may cover the display area DA and extend to the outside of the display area DA. The encapsulation layer 400 may include at least one organic encapsulation layer and at least one inorganic encapsulation layer. For example, the encapsulation layer 400 may include a first inorganic encapsulation layer 410, an organic encapsulation layer 420, and a second inorganic encapsulation layer 430.

As the first inorganic encapsulation layer 410 is formed along a structure disposed thereunder, a top surface of the first inorganic encapsulation layer 410 may be uneven. The organic encapsulation layer 420 may cover the first inorganic encapsulation layer 410, and unlike the first inorganic encapsulation layer 410, a top surface of the organic encapsulation layer 420 may be approximately even.

The first inorganic encapsulation layer 410 and the second inorganic encapsulation layer 430 may each include one or more organic materials among aluminum oxide, titanium oxide, tantalum oxide, hafnium oxide, zinc oxide, silicon oxide, silicon nitride, and silicon oxynitride. The organic encapsulation layer 420 may include a polymer-based material. The polymer-based material may include an acryl-based material, an epoxy-based material, polyimide, polyethylene, and the like. According to an embodiment, the organic encapsulation layer 420 may include acrylate. The organic encapsulation layer 420 may be formed by curing a monomer or coating a polymer.

Due to a multiple-layered structure of the encapsulation layer 400 described above, even in case that cracks occur in the encapsulation layer 400, the cracks may not be connected between the first inorganic encapsulation layer 410 and the organic encapsulation layer 420 or between the organic encapsulation layer 420 and the second inorganic encapsulation layer 430. Therefore, formation of a path through which external moisture or oxygen permeates into the display area DA may be prevented or minimized.

In some embodiments, other layers such as a capping layer may be disposed between the first inorganic encapsulation layer 410 and the counter electrode 330.

The color panel 20 may include the light-transmitting base layer 500, the color filter layer 600, and the function layer 700.

The light emitted by the emission panel 10 may include incident light that is incident to the color panel 20. For example, the light emitted from each of the first light-emitting diode LED1, the second light-emitting diode LED2, and the light-emitting diode LED3 may move to the color panel 20 as the incident light. A portion of the incident light may undergo color conversion through the color panel 20 and may be emitted to the outside, and another portion of the incident light may be emitted to the outside through the color panel 20 without color conversion.

The color panel 20 may include a center area CA overlapping the first light-emitting diode LED1, the second light-emitting diode LED2, and the third light-emitting diode LED3. In an embodiment, the center area CA may include a first center area CA1, a second center area CA2, and a third center area CA3. The first center area CA1 may overlap the first light-emitting diode LED1 and the first emission area EA1. The second center area CA2 may overlap the second light-emitting diode LED2 and the second emission area EA2. The third center area CA3 may overlap the third light-emitting diode LED3 and the third emission area EA3.

For example, the light (e.g., the blue light Lb) emitted from the first light-emitting diode LED1 may be converted into the red light Lr through the color panel 20 and may be emitted to the outside through the first center area CA1. The light (e.g., the blue light Lb) emitted from the second light-emitting diode LED2 may be converted into the green light Lg through the color panel 20 and may be emitted to the outside through the second center area CA2. The light (e.g., the blue light Lb) emitted from the third light-emitting diode LED3 may be emitted to the outside through the third center area CA3, without color conversion through the color panel 20. As described above, the color panel 20 may include the first center area CA1, the second center area CA2, and the third center area CA3 respectively overlapping the first light-emitting diode LED1, the second light-emitting diode LED2, and the third light-emitting diode LED3 and that emit light having different colors. The first center area CA1, the second center area CA2, and the third center area CA3 of the color panel 20 may respectively correspond to the first pixel PX1, the second pixel PX2, and the third pixel PX3 of the display device 1. Here, “correspond” may indicate overlapping each other when viewed in a direction (e.g., a +z direction) perpendicular to a surface of the light-transmitting base layer 500.

Hereinafter, a stack structure of the color panel 20 will be described in detail.

in an embodiment, the light-transmitting base layer 500 may include a substrate, i.e., a second substrate or an upper substrate disposed above the first substrate 100 with the light-emitting diodes therebetween. The light-transmitting base layer 500 may be disposed on the light-emitting diodes, i.e., the first light-emitting diode LED1, the second light-emitting diode LED2, and the third light-emitting diode LED3.

The light-transmitting base layer 500 may include glass or a high-molecular resin. In case that the light-transmitting base layer 500 is flexible or bendable, the light-transmitting base layer 500 may include a high-molecular material, e.g., polyethersulfone, polyacrylate, polyetherimide, polyethylene naphthalate, polyethylene terephthalate, polyphenylene sulfide, polyarylate, polyimide, polycarbonate, or cellulose acetate propionate.

The color filter layer 600 may be disposed on a bottom surface of the light-transmitting base layer 500 on the light-transmitting base layer 500 in a direction (e.g., a-z direction) toward the first substrate 100. The color filter layer 600 may include the first color filter 610, the second color filter 620, and the third color filter 630. The first color filter 610 may be arranged in the first center area CA1. The second color filter 620 may be arranged in the second center area CA2. The third color filter 630 may be arranged in the third center area CA3. The first color filter 610 may be arranged at a position corresponding to the first emission area EA1. The second color filter 620 may be arranged at a position corresponding to the second emission area EA2. The third color filter 630 may be arranged at a position corresponding to the third emission area EA3.

The first color filter 610, the second color filter 620, and the third color filter 630 may include a photosensitive resin. The first color filter 610, the second color filter 620, and the third color filter 630 may respectively include pigments or dyes having inherent colors.

The first color filter 610 may include a red color filter. For example, the first color filter 610 may only transmit light in a wavelength of from about 630 nm to about 780 nm. The first color filter 610 may include a red pigment or dye. The second color filter 620 may include a green color filter. For example, the second color filter 620 may only transmit light in a wavelength of from about 495 nm to about 570 nm. The second color filter 620 may include a green pigment or dye. The third color filter 630 may include a blue color filter. For example, the third color filter 630 may only transmit light in a wavelength of from about 450 nm to about 495 nm. The third color filter 630 may include a blue pigment or dye.

The color filter layer 600 may reduce reflection of external light of the display device 1. For example, in case that the external light reaches the first color filter 610, only light in a preset wavelength as described above may be transmitted through the first color filter 610, and light in other wavelengths may be absorbed by the first color filter 610. Therefore, from the external light incident to the display device 1, only the light in the preset wavelength may be transmitted through the first color filter 610, and some of the light may be reflected by the counter electrode 330 and/or the first pixel electrode 310R under the first color filter 610 and may be emitted again to the outside. As only a portion of the external light incident to a position of the first pixel PX1 is reflected to the outside, reflection of the external light may be reduced. The description may also be applied to the second color filter 620 and the third color filter 630.

The first color filter 610, the second color filter 620, and the third color filter 630 may overlap one another. The first color filter 610, the second color filter 620, and the third color filter 630 may overlap one another between any one of the center areas CA and another one of the center areas CA.

For example, the first color filter 610, the second color filter 620, and the third color filter 630 may overlap between the first center area CA1 and the second center area CA2. In this case, the third color filter 630 may be arranged between the first center area CA1 and the second center area CA2. The first color filter 610 may extend from the first center area CA1 and overlap the third color filter 630. The second color filter 620 may extend from the second center area CA2 and overlap the third color filter 630.

For example, the first color filter 610, the second color filter 620, and the third color filter 630 may overlap between the second center area CA2 and the third center area CA3. The first color filter 610 may be disposed between the second center area CA2 and the third center area CA3. The second color filter 620 may extend from the second center area CA2 and overlap the first color filter 610. The third color filter 630 may extend from the third center area CA3 and overlap the first color filter 610.

For example, the first color filter 610, the second color filter 620, and the third color filter 630 may overlap between the third center area CA3 and the first center area CA1. The second color filter 620 may be arranged between the third center area CA3 and the first center area CA1. The third color filter 630 may extend from the third center area CA3 and overlap the second color filter 620. The first color filter 610 may extend from the first center area CA1 and overlap the second color filter 620.

As described above, the first color filter 610, the second color filter 620, and the third color filter 630 may overlap to define a blocking portion BP. As another embodiment, the blocking portion BP may be formed as two color filter materials selected from among the first color filter 610, the second color filter 620, and the third color filter 630 overlap each other. Therefore, the color filter layer 600 may prevent or reduce color mixture without additional blocking members.

A low-refractive layer LRL may be disposed on the color filter layer 600. The low-refractive layer LRL may be disposed between the function layer 700 and the color filter layer 600. In an embodiment, the low-refractive layer LRL may be disposed between the color filter layer 600 and a first capping layer The low-refractive layer LRL may be disposed on an entire portion of the color filter layer 600. For example, the low-refractive layer LRL may be generally disposed on the first color filter 610, the second color filter 620, and the third color filter 630. In an embodiment, the low-refractive layer LRL may contact the first capping layer CL1. In an embodiment, a refractive index of the low-refractive layer LRL may be less than a refractive index of the first capping layer CL1. In an embodiment, the refractive index of the low-refractive layer LRL may also be less than a refractive index of the color filter layer 600. For example, the low-refractive layer LRL may have a refractive index equal to or greater than about 1.1 and less than or equal to about 1.4. In an embodiment, the refractive index of the low-refractive layer LRL may be less than a refractive index of the function layer 700. In some embodiments, the low-refractive layer LRL may be omitted.

The low-refractive layer LRL may include an organic material and particles distributed in the organic material. For example, the low-refractive layer LRL may include ZnO particles, TiO2 particles, hollow silica particles being empty inside, silica particles not being empty inside, nano-silicate particles, and/or porogen particles.

The low-refractive layer LRL may reflect some of the light emitted from the function layer 700 in a direction toward the light-transmitting base layer 500 again toward the function layer 700. For example, the low-refractive layer LRL may recycle at least some of the light penetrating the function layer 700 and emitted in the direction toward the light-transmitting base layer 500, thereby improving light use efficiency and light efficiency of the display device 1.

The first capping layer CL1 may be disposed on the low-refractive layer LRL. In an embodiment, the first capping layer CL1 may be disposed between the color filter layer 600 and the function layer 700. In an embodiment, the first capping layer CL1 may be disposed between the low-refractive layer LRL and the function layer 700. The first capping layer CL1 may protect the low-refractive layer LRL and the color filter layer 600. The first capping layer CL1 may prevent or reduce damage or contamination of the low-refractive layer LRL and/or the color filter layer 600 due to permeation of impurities such as moisture and/or air from the outside. The first capping layer CL1 may include an inorganic material. In some embodiments, the first capping layer CL1 may also be omitted.

A bank layer 800 may be disposed on the first capping layer CL1. The bank layer 800 may include an organic material. According to an embodiment, the bank layer 800 may include a light-blocking material to function as a light-blocking layer. The light-blocking material may include at least one of a black pigment, black dye, black particles, and metal particles.

Openings COP may be defined as partitions in the bank layer 800. The openings COP may overlap the center areas CA. The openings COP of the bank layer 800 may include a first opening COP1, a second opening COP2, and a third opening COP3. For example, the first opening COP1 overlapping the first center area CA1, the second opening COP2 overlapping the second center area CA2, and the third opening COP3 overlapping the third center area CA3 may be defined in the bank layer 800.

The function layer 700 may fill the openings COP of the bank layer 800. As shown in FIG. 5, the function layer 700 may include the base resin BR in which the pores 1200 are defined. In some embodiments, the function layer 700 may include at least one of quantum dots and scattered particles. In an embodiment, the function layer 700 may include the first color conversion layer 710, the second color conversion layer 720, and the transmitting layer 730. The first color conversion layer 710, the second color conversion layer 720, and the transmitting layer 730 may be distinguished by the partitions in the bank layer 800.

The first color conversion layer 710 may correspond to the first center area CA1. The first color conversion layer 710 may overlap the first center area CA1. The first color conversion layer 710 may fill the first opening COP1 of the bank layer 800. The first color conversion layer 710 may overlap the first emission area EA1. The first color conversion layer 710 may be arranged in a direction (e.g., the z direction) in which the first light-emitting diode LED1 emits light.

The first color conversion layer 710 may convert light of the first wavelength band, which is generated in the emission layer 320 on the first pixel electrode 310R, into light of the second wavelength band. In an embodiment, the first color conversion layer 710 may convert blue light into red light. For example, in case that light of a wavelength from about 450 nm to about 495 nm is generated in the emission layer 320 on the first pixel electrode 310R, the first color conversion layer 710 may convert the light into light of a wavelength band from about 630 nm to about 780 nm. Accordingly, light in a wavelength band of from about 630 nm to about 780 nm may be emitted outside through the light-transmitting base layer 500.

The second color conversion layer 720 may correspond to the second center area CA2. The second color conversion layer 720 may overlap the second center area CA2. The second color conversion layer 720 may fill the second opening COP2 of the bank layer 800. The second color conversion layer 720 may overlap the second emission area EA2. The second color conversion layer 720 may be arranged in a direction (e.g., the z direction) in which the second light-emitting diode LED2 emits light.

The second color conversion layer 720 may convert light in the first wavelength band, which is generated in the emission layer 320 of the second pixel electrode 310G, into light in the third wavelength band. For example, the second color conversion layer 720 may convert blue light into green light. For example, in case that light having a wavelength of from about 450 nm to about 495 nm is generated in the emission layer 320 on the second pixel electrode 310G, the second color conversion layer 720 may convert the light into light having a wavelength of from about 495 nm to about 570 nm. Accordingly, light having the wavelength of from about 495 nm to about 570 nm may be emitted outside through the light-transmitting base layer 500.

The transmitting layer 730 may correspond to the third center area CA3. The transmitting layer 730 may overlap the third center area CA3. The transmitting layer 730 may fill the third opening COP3 of the bank layer 800. The transmitting layer 730 may overlap the third emission area EA3. The transmitting layer 730 may be arranged in a direction in which the third light-emitting diode LED3 emits light (e.g., the z direction).

The transmitting layer 730 may emit the light generated in the emission layer 320 on the third pixel electrode 310B to the outside without wavelength conversion. For example, the transmitting layer 730 may transmit the blue light without conversion. For example, in case that light having a wavelength of from about 450 nm to about 495 nm is generated in the emission layer 320 on the third pixel electrode 310B, the transmitting layer 730 may emit the light to the outside without wavelength conversion.

As shown in FIG. 5, the function layer 700 may include the base resin BR in which the pores 1200 are defined. The pores 1200 included in the base resin BR may include bubbles or empty spaces formed by porogen described herein. The first color conversion layer 710 may include a first base resin 1151 in which pores 1201 are defined. The second color conversion layer 720 may include a second base resin 1161 in which pores 1202 are defined. The transmitting layer 730 may include a third base resin 1171 in which pores 1203 are defined.

The base resin BR may include, for example, a light-transmitting organic material. The base resin BR may include, for example, a photosensitive polymer. The first base resin 1151, the second base resin 1161, and the third base resin 1171 may include, for example, light-transmitting organic materials. The first base resin 1151, the second base resin 1161, and the third base resin 1171 may include, for example, a photosensitive polymer. In an embodiment, the first base resin 1151, the second base resin 1161, and the third base resin 1171 may each include a photosensitive polymer having an excellent scattering characteristic and transmittance. For example, the first base resin 1151, the second base resin 1161, and the third base resin 1171 may each include an acryl-based resin, an imide-based resin, an epoxy-based resin, and/or the like.

In an embodiment, the first base resin 1151 and the second base resin 1161 may include a same material. In an embodiment, the third base resin 1171 and the first base resin 1151 may include a same material. For example, the first base resin 1151, the second base resin 1161, and the third base resin 1171 may include organic materials having a same light transmittance.

A size of each of the pores 1200 defined in the base resin BR may be greater than a size of each of first quantum dots 1152 included in the first color conversion layer 710 and a size of each of second quantum dots 1162 included in the second color conversion layer 720. The size of each of the pores 1200 defined in the base resin BR may be in a range from about 30 nm to about 70 nm. The size of each of the pores 1200 may be in a range from about 40 nm to about 60 nm. In this case, the size of each of the pores 1200 may be defined as a diameter of each of the pores 1200.

In an embodiment, a porosity of the first color conversion layer 710, a porosity of the second color conversion layer 720, and a porosity of the transmitting layer 730 may be identical to one another, but the disclosure is not limited thereto. In another embodiment, the porosity of the first color conversion layer 710, the porosity of the second color conversion layer 720, and the porosity of the transmitting layer 730 may be different from one another. For example, the porosity of the first base resin 1151 of the first color conversion layer 710, the porosity of the second base resin 1161 of the second color conversion layer 720, and the porosity of the third base resin 1171 of the transmitting layer 730 may be identical to or different from one another.

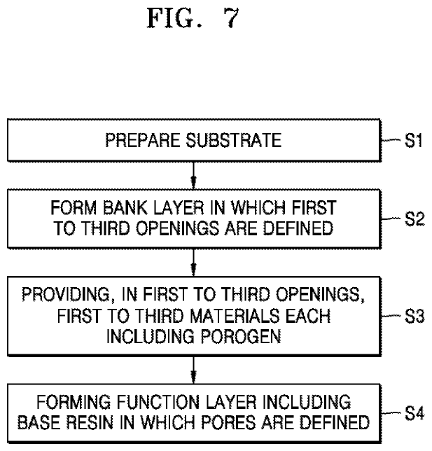

In a process of manufacturing the display device 1 described with reference to FIG. 7, porogen may be mixed in a uniform content ratio with the materials included in the first color conversion layer 710, the second color conversion layer 720, and the transmitting layer 730, such that the porosity of the first color conversion layer 710, the second color conversion layer 720, and the transmitting layer 730 are identical to one another, the disclosure is not limited thereto. For example, in the process of manufacturing the display device 1, by modifying a content ratio of porogen according to conditions, the porosities of the first color conversion layer 710, the second color conversion layer 720, and transmitting layer 730 may be different from one another.

As the function layer 700 includes the base resin BR in which the pores 1200, a reflective index of the function layer 700 may be less than a refractive index in case that the function layer 700 does not include the pores 1200. The refractive index of the function layer 700 may be, e.g., equal to or greater than about 1.5 and less than or equal to about 1.7. In an embodiment, a refractive index of the first color conversion layer 710 may be, e.g., equal to or greater than about 1.5 and less than or equal to about 1.7. In an embodiment, a refractive index of the second color conversion layer 720 may be, e.g., equal to or greater than about 1.5 and less than or equal to about 1.7. In an embodiment, the refractive index of the transmitting layer 730 may be, e.g., equal to or greater than about 1.5 and less than or equal to about 1.7. A difference between the refractive index of the function layer 700 and the refractive index of the low-refractive layer LRL may be in a range of, e.g., from about 0.1 to about 0.6. As the refractive index of the function layer 700 becomes relatively small, light efficiency of the color panel 20 may be further improved.

In an embodiment, as shown in FIG. 5, the first color conversion layer 710 may include the first base resin 1151, in which the pores 1201 are defined, and the first quantum dots 1152 and first scattered particles 1153 distributed in the first base resin 1151. The first quantum dots 1152 may be excited by the blue light Lb and may isotopically emit the red light Lr having a wavelength longer than a wavelength of the blue light Lb. The first scattering particles 1153 may scatter the blue light Lb that has not been absorbed into the first quantum dots 1152, such that a greater number of the first quantum dots 1152 are excited, to thereby improve color conversion efficiency. The first scattered particles 1153 may include, e.g. titanium oxide (TiO₂), metal particles, and/or the like. The first quantum dots 1152 may be selected from among a Group II-VI compound, a Group III-V compound, a Group IV-VI compound, a Group IV element, a Group IV compound, and combinations thereof.

In an embodiment, as shown in FIG. 5, the second color conversion layer 720 may include the second base resin 1161, in which the pores 1202 are defined, and the second quantum dots 1162 and second scattered particles 1163 distributed in the second base resin 1161. The second quantum dots 1162 may be excited by the blue light Lb and may isotopically emit the green light Lg having a wavelength longer than a wavelength of the blue light. The second scattering particles may scatter the blue light Lb that has not been absorbed into the second quantum dots 1162, such that a greater number of the second quantum dots 1162 are excited, to thereby improve color conversion efficiency. The second scattered particles 1163 may include, e.g., TiO₂ or metal particles. The second quantum dots 1162 may include a Group III-VI compound, a Group III-V compound, a Group III-VI compound, a Group I-III-VC compound, a Group IV-VI compound, a Group IV element or compound, or arbitrary combinations thereof.

In an embodiment, as shown in FIG. 5, the transmitting layer 730 may include a third base resin 1171, in which the pores 1203 are defined, and third scattered particles 1173 distributed in the third base resin 1171. In an embodiment, the transmitting layer 730 may not include quantum dots. The third scattering particles 1173 may scatter and emit the blue light Lb, and may include a same material as that of the first scattering particles 1153 and the second scattering particles 1163.

At least one of the first quantum dots 1152 and the second quantum dots 1162 may include a semiconductor material such as cadmium sulfide (CdS), cadmium telluride (CdTe), zinc sulfide (ZnS), indium phosphide (InP), or the like. A size of the quantum dots may be several nanometers. For example, a size of each of the first quantum dots 1152 and the second quantum dots 1162 may be in a range from about 2 nm to about 10 nm. In this case, the size of each of the first quantum dots 1152 and the second quantum dots 1162 may be defined as a diameter of each of the first quantum dots 1152 and the second quantum dots 1162. According to the size of the quantum dots, light after conversion may have different wavelengths.

In the specification, a quantum dot may indicate a crystal of a semiconductor compound, and may include an arbitrary material capable of emitting light in various wavelength bands according to a size of the crystal.

The first quantum dots 1152 may be synthesized through a wet etching process, an organic metal chemical vapor process, a molecule line epitaxy process, and/or other similar processes. The wet etching process may be a method of mixing an organic solvent and a precursor material and growing quantum-dot particle crystals. In case that the crystals are grown, an organic solvent may naturally function as a distributor coordinated to a surface of a quantum-dot crystal and adjust growth of the crystal. Therefore, the wet etching process is easier to perform than vapor deposition methods such as metal organic chemical vapor deposition (MOCVD) or molecular beam epitaxy (MBE), and the growth of the quantum-dot particles may be controlled through a low-cost process.

The second quantum dots 1162 may include a same material and have a same shape as the first quantum dots 1152. However, the size of each of the second quantum dots 1162 may be different from the size of each of the first quantum dots 1152. For example, the size of each of the second quantum dots 1162 may be less than the size of each of the first quantum dots 1152. This is to have the second quantum dots 1162 emit light in a wavelength band different from a wavelength band to which the first quantum dots 1152 belong. More particularly, an energy band gap may be adjusted by adjusting the size of the quantum dots, and accordingly, light in various wavelength bands may be obtained. The size of each of the second quantum dots 1162 may be less than the size of each of the first quantum dots 1152, and therefore, the second quantum dots 1162 may isotopically emit the green light Lg that is excited by the blue light Lb and has a wavelength greater than a wavelength of the blue light and less than a wavelength of the red light Lr.

In an embodiment, a core of the first quantum dots 1152 and a core of the second quantum dots 1162 may each be selected from among a Group III-VI compound, a Group II-VI compound, a Group III-V compound, a Group III-VI compound, a Group I-III-VI compound, a Group IV-VI compound, a Group IV element or compound, or arbitrary combinations thereof.

The Group II-VI compound may be selected from among a group including a two-element compound selected from among a group including CdSe, CdTe, ZnS, ZnSe, ZnTe, ZnO, HgS, HgSe, HgTe, MgSe, MgS, and a mixture thereof; a three-element compound selected from among a group including AglnS, CuInS, CdSeS, CdSeTe, CdSTe, ZnSeS, ZnSeTe, ZnSTe, HgSeS, HgSeTe, HgSTe, CdZnS, CdZnS, CdZnTe, CdHgS, CdHgSe, CdHgTe, HgZnS, HgZnSe, HgZnTe, MgZnSe, MgZnS, and a mixture thereof; and a four-element compound selected from among a group including HgZnTeS, CdZnSeS, CdZnSeTe, CdZnSTe, CdHgSeS, CdHgSeTe, CdHgSTe, HgZnSeSn, HgZnSeTe, HgZnSTe, and a mixture thereof.

The Group III-V compound may be selected from among a group including: a two-element compound selected from among a group including GaN, GaP, GaAs, GaSb, AlN, AIP, AIAs, AISb, InN, InP, InAs, InSb, and a mixture thereof; a three-element compound selected from among a group including GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and a mixture thereof; and a four-element compound selected from among a group including GaAlNAs, GaAlNSb, GaAlPAs, GaAlPSb, GaInNP, GaInNAs, GaInNSb, GaInPAs, GaInPSb, InAlNP, InAlNAs, InAlNsb, InAlPAs, InAlPSb, and a mixture thereof. The Group III-V compound may further include a Group II element. The Group III-V compound further including the Group II element may include InZnP, InGaZnP, InAlZnP, and the like.

The Group III-VI compound may include a two-element compound such as GaS, Ga₂S₃, GaSe, Ga₂Se₃, GaTe, InS, InSe, In₂S₃, In₂Se₃, or InTe, a three-element such as InGaS₃ or InGaSe₃, or an arbitrary combination thereof.

The Group I-III-VI compound may include a three-lement compound such as AglnS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO₂, a four-element compound such as AgInGaSe or AgInGaSe₂, or an arbitrary combination thereof. The Group IV-VI compound may include a two-element compound selected from among a group including SnS, SnSe, SnTe, PbS, PbSe, PbTe and a combination thereof, a three-element compound selected from among a group including SnSeS, SnSeTe, SnSTe, PbSeS, PbSeTe, PbSTe, SnPbS, SnPbSe, SnPbTe, and a combination thereof, and a four-element compound selected from among a group including SnPbSSe, SnPbSeTe, SnPbSTe, and a combination thereof. The Group IV element may be selected from among a group including Si, Ge, and a combination thereof. The Group IV compound may include a two-element compound selected from among a group including SiC, SiGe, and a combination thereof.

In this case, the two-element compound, the third-element compound, or the four-element compound may exist in the particle in a uniform concentration, or may exist in a same particle in partially non-uniform concentration distribution. For example, the formula may indicate kinds of elements included in the compounds, and the compounds may have different element ratios. For example, AgInGaS₂ may indicate AgInGa₁₋ₓS₂ (where x is an actual number between 0 and 1).

Each of the first quantum dots 1152 and the second quantum dots 1162 may have a core/shell structure in which one quantum dot surrounds another quantum dot. An interface between the core and the shell may have a concentration gradient in which a concentration of an element in the shell decreases toward a center.

In some embodiments, the first quantum dots 1152 and the second quantum dots 1162 may each have a core-shell structure including a core including the aforementioned nanocrystal and the shell surrounding the core. The shell of the quantum dots may function as a protective layer to maintain semiconductor characteristics by preventing chemical modification of the core and/or a charging layer to give an electrophoretic characteristic to the quantum dots. The shell may include a single layer or multiple layers. An interface between the core and the shell may have a concentration gradient in which a concentration of an element in the shell decreases toward a center. An example of the shell of the quantum dots may include an oxide of a metal or a non-metal, a semiconductor compound, or combinations thereof.

For example, the oxide of a metal or a non-metal may include, e.g., a two-element compound such as SiOₓ, Al₂O₃, TiO₂, ZnOₓ, MnO, Mn₂O₃, Mn₃O₄, CuO, FeO, Fe₂O₃, Fe₃O₄, CoO, Co₃O₄, NiO, and a three-element compound such as MgAl₂O₄, CoFe₂O₄, NiFe₂O₄, CoMn₂O₄, but the disclosure is not limited thereto.

The semiconductor compound may include, e.g., CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, but the disclosure is not limited thereto.

Elements included in multi-element compounds such as the two-element compound and the three-element compound may exist in the particle in a concentration with uniformity or non-uniformity. For example, the formula may indicate kinds of elements included in the compounds, and the compounds may have different element ratios.

In an embodiment, the first quantum dots 1152 and the second quantum dots 1162 may each have a full width of half maximum (FWHM) of an emission wavelength spectrum in about 45 nm or less, in an embodiment about 40 nm or less, in another embodiment about 30 nm or less, and color purity or color reproducibility may be improved in the aforementioned range. The light emitted through the quantum dots may be emitted in every direction, and therefore, a viewing angle of the light may be improved.

Although the form of each of the first quantum dots 1152 and the second quantum dots 1162 includes general shapes used in the field and is not particularly limited, more specifically, may include the form of nanoparticles, nanotubes, nanowires, nanofibers, nano platelet particles having a spherical shape, a pyramid shape, a multi-arm shape, or a cubic shape.

The first quantum dots 1152 and the second quantum dots 1162 may adjust color of the emitted light according to sizes of the particles, and therefore, the first quantum dots 1152 and the second quantum dots 1162 may emit light having various colors such as blue, red, and green.

The first scattering particles 1153, the second scattering particles 1163, and the third scattering particles 1173 may scatter the light such that a greater amount of light may be emitted. The first scattering particles 1153, the second scattering particles 1163, and the third scattering particles 1173 may improve emission efficiency. At least one of the first scattering particles 1153, the second scattering particles 1163, and the third scattering particles 1173 may include any material among metals or metal oxides for evenly scattering the light. For example, at least one of the first scattering particles 1153, the second scattering particles 1163, and the third scattering particles 1173 may include at least one of TiO₂, ZrO₂, Al₂O₃, In₂O₃, ZnO, SnO₂, Sb₂O₃, and ITO. At least one of the first scattering particles 1153, the second scattering particles 1163, and the third scattering particles 1173 may have a refractive index of about 1.5 or greater. Accordingly, emission efficiency of the function layer 700 may be improved. In some embodiments, at least one of the first scattering particles 1153, the second scattering particles 1163, and the third scattering particles 1173 may be omitted.

Referring again to FIG. 4, a second capping layer CL2 may be disposed on the function layer 700 and the bank layer 800. In an embodiment, the second capping layer CL2 may be disposed under the function layer 700. In an embodiment, the second capping layer CL2 may be disposed on a bottom surface of the function layer 700 and a bottom surface of the bank layer 800 on the light-transmitting base layer 500 in a direction toward the first substrate 100 (e.g., the −z direction). In an embodiment, the second capping layer CL2 may be disposed between the function layer 700 and the filler layer 30, and may also be disposed between the bank layer 800 and the filler layer 30. The second capping layer CL2 may protect the function layer 700 and the bank layer 800.

The second capping layer CL2 may prevent or reduce damage or contamination of the function layer 700 and/or the bank layer 800 due to permeation of impurities such as moisture and/or air from the outside. The second capping layer CL2 may include an inorganic material. In some embodiments, the second capping layer CL2 may also be omitted.

In an embodiment, the filler layer 30 may be disposed between the second capping layer CL2 and the encapsulation layer 400.

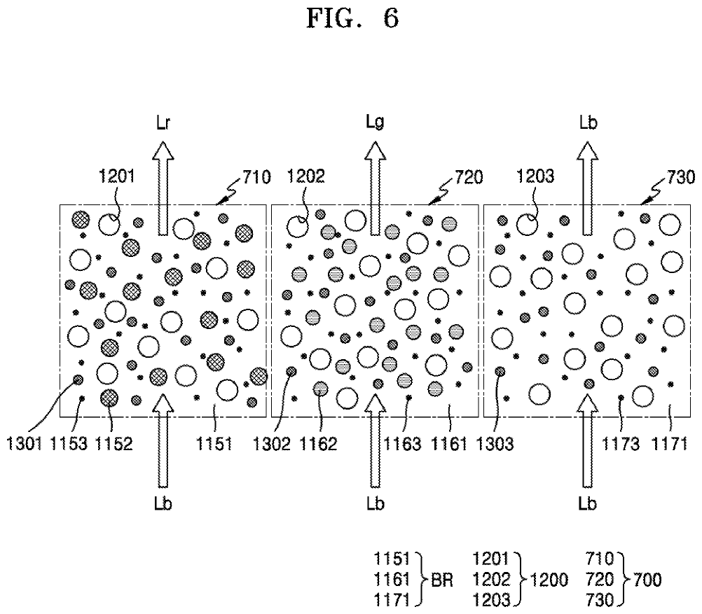

FIG. 6 schematically illustrates an enlarged image of the function layer 700 according to another embodiment of the disclosure. Description of FIG. 6 identical to the descriptions with reference to FIGS. 4 and 5 will be omitted, and changes will be described.

Referring to FIG. 6, the function layer 700 may further include low-refractive objects (i.e., first low-refractive objects 1301, second low-refractive objects 1302, and third low-refractive objects 1303) distributed in the base resin BR in which the pores 1200 are defined. The low-refractive objects may include the first low-refractive objects 1301 included in the first color conversion layer 710, the second low-refractive objects 1302 included in the second color conversion layer 720, and the third low-refractive objects 1303 included in the transmitting layer 730.

A refractive index of each of the first low-refractive objects 1301, the second low-refractive objects 1302, and the third low-refractive objects 1303 may be greater than about 1.0 and less than or equal to about 1.3. The first low-refractive objects 1301, the second low-refractive objects 1302, and the third low-refractive objects 1303 may include, for example, zinc oxide (ZnO) particles, titanium dioxide (TiO₂) particles, hollow silica particles, non-hollow silica particles, and/or nano silicate particles. In an embodiment, the low-refractive layer LRL may include materials identical to those of the first low-refractive objects 1301, the second low-refractive objects 1302, and the third low-refractive objects 1303, but the disclosure is not limited thereto. In another embodiment, the low-refractive layer LRL may include material different from those of the first low-refractive objects 1301, the second low-refractive objects 1302, and the third low-refractive objects 1303. Particles distributed in the organic material of the low-refractive layer LRL may include materials identical to or different from the materials of the first low-refractive objects 1301, the second low-refractive objects 1302, and the third low-refractive objects 1303.

In the embodiment, as the function layer 700 further includes the first low-refractive objects 1301, the second low-refractive objects 1302, and the third low-refractive objects 1303, the refractive index of the function layer 700 may be less than in the embodiment described with reference to FIG. 5. As the refractive index of the function layer 700 becomes relatively small, the light efficiency of the color panel 20 may be improved.

FIG. 7 is a flowchart showing a method of manufacturing the display device 1 according to an embodiment of the disclosure.

Referring to FIG. 7, the method of manufacturing the display device 1 may include preparing a substrate (S1), forming a bank layer in which a first opening, a second opening, and a third opening are defined (S2), providing a first material, a second material, and a third material including porogen respectively to the first opening, the second opening, and the third opening (S3), and forming a function layer including a base resin in which pores are defined (S4).

First, the substrate may be prepared. In the preparing of the substrate, the substrate may include glass material, ceramic material, a metal material, and/or a material that is flexible or bendable. In case that the substrate is flexible or bendable, the substrate may include a high-molecular resin such as polyethersulfone, polyacrylate, polyetherimide, polyethylene naphthalate, polyethylene terephthalate, polyphenylene sulfide, polyarylate, polyimide, polycarbonate, and/or cellulose acetate propionate.

Referring to FIGS. 4 and 7, in the preparing of the substrate (S1), the substrate may include the first substrate 100 or the light-transmitting base layer 500. In the display device 1 according to an embodiment, in which the emission panel 10 and the color panel 20 are respectively formed and combined to one another, the preparing of the substrate (S1) may include preparing the light-transmitting base layer 500 corresponding to the upper substrate. In the display device 1 according to another embodiment in which the function layer 700 and the color filter layer 600 are sequentially formed on the encapsulation layer 400, the preparing of the substrate (S1) may include preparing the first substrate 100.

The bank layer, in which the first opening, the second opening, and the third opening are defined, may be formed on the substrate (S2). In the forming of the bank layer (S2), an organic material layer may be formed on the substrate, and the bank layer 800 (see FIG. 4), in which the first opening COP1, the second opening COP2, and the third opening COP3 (see FIG. 4) are defined, by removing a portion of the organic material layer. According to an embodiment, the bank layer 800 may include a light-blocking material to function as a light-blocking layer. The light-blocking material may include at least one of a black pigment, black dye, black particles, and metal particles.

In the display device 1 according to an embodiment, in which the emission panel 10 and the color panel 20 are separately formed and combined to each other, before the forming of the bank layer (S2), the method may further include forming, on the substrate, the color filter layer including the first color filter, the second color filter, and the third color filter. The method may further include, on the color filter layer, forming a low-refractive layer having a refractive index less than a refractive index of the color filter layer. The low-refractive layer may be generally disposed on the color filter layer.

Referring to FIGS. 4 and 7, the first color filter 610, the second color filter 620, and the third color filter 630 may each include a photosensitive resin. The first color filter 610, the second color filter 620, and the third color filter 630 may respectively include pigments or dyes having inherent colors. The descriptions of the first color filter 610, the second color filter 620, and the third color filter 630, with reference to FIG. 4, may also be applied to the display device 1 shown in FIG. 1. The refractive index of the low-refractive layer LRL may be less than the refractive index of the color filter layer 600. For example, the refractive index of the low-refractive layer LRL may be equal to or greater than about 1.1 and less than or equal to about 1.4. The low-refractive layer LRL may include an organic material and particles distributed in the organic material. For example, the low-refractive layer LRL may include ZnO particles, TiO₂ particles, hollow silica particles being empty inside, silica particles not being empty inside, nano silicate particles, and/or porogen particles.

First to third materials including porogen may be respectively provided in the first opening COP1, the second opening COP2, and the third opening COP3 (see FIG. 4) in the bank layer 800 (see FIG. 4) (S3).

The first material, i.e., a mixture of the first base resin 1151 (see FIG. 5), porogen, and the first quantum dots 1152 (see FIG. 5), may be provided in the first opening COP1 of the bank layer 800. The second material, i.e., a mixture of the second base resin 1161 (see FIG. 5), porogen, and the second quantum dots 1162 (see FIG. 5), may be provided in the second opening COP2 of the bank layer 800. The third material, i.e., a mixture of the third base resin 1171 (see FIG. 5) and porogen, may be provided in the third opening COP3 of the bank layer 800. Description of the first quantum dots 1152 and the second quantum dots 1162 may be identical to the description with reference to FIGS. 4 and 5.

In an embodiment, content ratios of porogen included in the first to third materials may be identical to one another, however, the disclosure is not limited thereto. In another embodiment, content ratios of porogen included in the first to third materials may be different from one another. According to embodiments, content ratios of porogen used in the manufacturing process for securing characteristics of light may be adjusted to be identical to or different from each other.

The first base resin 1151, the second base resin 1161, and the third base resin 1171 may include, for example, light-transmitting organic materials. The first base resin 1151, the second base resin 1161, and the third base resin 1171 may include, for example, a photosensitive polymer. In an embodiment, the first base resin 1151, the second base resin 1161, and the third base resin 1171 may each include a photosensitive polymer having an excellent scattering characteristic and transmittance. For example, the first base resin 1151, the second base resin 1161, and the third base resin 1171 may each include an acryl-based resin, an imide-based resin, an epoxy-based resin, and/or the like.

In an embodiment, the first base resin 1151 and the second base resin 1161 may include a same material. In an embodiment, the third base resin 1171 and the first base resin 1151 may include a same material. For example, the first base resin 1151, the second base resin 1161, and the third base resin 1171 may include organic materials having a same light transmittance.

In an embodiment, the first material may further include the first scattering particles 1153, the second material may further include the second scattering particles 1163, and the third material may further include the third scattering particles 1173. Descriptions of the first scattering particles 1153, the second scattering particles 1163, and the third scattering particles 1173 may be identical to the description with reference to FIGS. 4 and 5.

In an embodiment, the first material may further include the first low-refractive object 1301, the second material may further include the second low-refractive object 1302, and the third material may further include the third low-refractive object 1303. The refractive index of each of the first low-refractive objects 1301, the second low-refractive objects 1302, and the third low-refractive objects 1303 may be greater than about 1.0 and less than or equal to about 1.3. The first low-refractive objects 1301, the second low-refractive objects 1302, and the third low-refractive objects 1303 may include, for example, zinc oxide (ZnO) particles, titanium dioxide (TiO₂) particles, hollow silica particles, non-hollow silica particles, and/or nano silicate particles.

A function layer including a first color conversion layer, a second color conversion layer, and a transmitting layer each including a base resin in which pores are defined, by heating the first material, the second material, and the third material (S3). The refractive index of the function layer 700 that has been formed may be, e.g., equal to or greater than about 1.4 and less than or equal to about 1.7.

In an embodiment, a process of heating the first to third material may be performed by providing the first to third materials to the first opening, the second opening, and the third opening of the bank layer and directly heating the first to third materials, but the process is not limited thereto. For example, the heating of the first material, the second material, and the third material may be performed through a heating process performed in a following process to form another component.

When the first to third materials each including porogen are heated, bubbles may be generated. Accordingly, the pores 1201, 1202, and 1203 (see FIG. 5) may be defined in the first base resin 1151, the second base resin 1161, and the third base resin (see FIG. 5) respectively included in the first material, the second material, and the third material.

A size of each of the pores 1201, 1202, and 1203 respectively defined in the first base resin 1151, the second base resin 1161, and the third base resin 1171 may be greater than the size of the first quantum dots 1152 included in the first color conversion layer 710 (see FIG. 4) and the size of the second quantum dots 1162 included in the second color conversion layer 720 (see FIG. 4). A size of the pores 1201, 1202, and 1203 respectively defined in the first base resin 1151, the second base resin 1161, and the third base resin 1171 may be in a range from about 30 nm to about 70 nm. The size of each of the pores 1200 may be in a range from about 40 nm to about 60 nm. In this case, the size of each of the pores 1201, 1202, and 1203 may be defined as a diameter of each of the pores 1201, 1202, and 1203.

According to content ratios of porogen included in the first through third materials, the pores 1201 in the first base resin 1151, the pores 1202 in the second base resin 1161, and the pores 1203 in the third base resin 1171 may have a same ratio or different ratios. Porosities of the first base resin 1151, the second base resin 1161, and the third base resin 1171 may be formed to have a same ratio or different ratios.

Accordingly, the first color conversion layer 710 including the first base resin 1151 in which the pores 1201 are deformed and the first quantum dots 1152 may be formed. In an embodiment, the first color conversion layer 710 may further include the first scattering particles 1153 (see FIG. 5). In an embodiment, the first color conversion layer 710 may further include the first low-refractive objects 1301 (see FIG. 6).

Accordingly, the second color conversion layer 720 including the second base resin 1161 in which the pores 1202 are defined and the second quantum dots 1162 may be formed. In an embodiment, the second color conversion layer 720 may further include the second scattering particles 1163 (see FIG. 5). In an embodiment, the second color conversion layer 720 may further include the second low-refractive objects 1302 (see FIG. 6).

Accordingly, the transmitting layer 730 including the third base resin 1171 in which the pores 1203 are defined may be formed. In an embodiment, the transmitting layer 730 may further include the third scattering particles 1173 (see FIG. 5). In an embodiment, the transmitting layer 730 may further include the third low-refractive objects 1303 (see FIG. 6).

According to an embodiment of the disclosure, as the function layer including the first color conversion layer, the second color conversion layer, and the light-transmitting layer includes a base resin in which the pores are defined, the refractive index of the function layer relatively decreases, and thus, the emission efficiency may be improved. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope of the disclosure.

What is claimed is:

1. A display device, comprising:
a first pixel, a second pixel, and a third pixel emitting light of different colors;
light-emitting diodes that correspond to the first pixel, the second pixel, and the third pixel and that emit light of a same color; and
a function layer disposed in a direction in which the light-emitting diodes emit light, the function layer comprising:
a first color conversion layer corresponding to a first emission area of the first pixel;
a second color conversion layer corresponding to a second emission area of the second pixel; and
a transmitting layer corresponding to a third emission area of the third pixel, wherein
the first color conversion layer comprises first quantum dots,
the second color conversion layer comprises second quantum dots, and
each of the first color conversion layer, the second color conversion layer, and the transmitting layer comprises a base resin in which a plurality of pores are defined.

2. The display device of claim 1, wherein
a size of each of the plurality of pores is greater than a size of each of the first quantum dots, and
the size of each of the plurality of pores is greater than a size of each of the second quantum dots.

3. The display device of claim 1, wherein each of the first color conversion layer, the second color conversion layer, and the transmitting layer comprises scattering particles and low-refractive objects having a refractive index greater than about 1.0 and less than or equal to about 1.3.

4. The display device of claim 1, further comprising:
a color filter layer including:
a first color filter disposed corresponding to the first emission area;
a second color filter disposed corresponding to the second emission area; and
a third color filter disposed corresponding to the third emission area.

5. The display device of claim 4, further comprising:
a low-refractive layer disposed between the function layer and the color filter layer and having a refractive index less than a refractive index of the color filter layer.

6. The display device of claim 5, wherein the low-refractive layer has a refractive index less than a refractive index of the function layer.

7. The display device of claim 5, wherein a difference between the refractive index of the low-refractive layer and the refractive index of the function layer is greater than or equal to about 0.1 and less than or equal to about 0.6.

8. The display device of claim 5, wherein
each of the first color conversion layer, the second color conversion layer, and the transmitting layer further comprises scattering particles and low-refractive objects having a refractive index greater than about 1.0 and less than or equal to about 1.3, and
the low-refractive layer and the low-refractive objects include a same material.

9. The display device of claim 5, wherein
each of the first color conversion layer, the second color conversion layer, and the transmitting layer further comprises scattering particles and low-refractive objects having a refractive index greater than about 1.0 and less than or equal to about 1.3, and
the low-refractive layer and the low-refractive objects include a different material.

10. The display device of claim 1, wherein a refractive index of the function layer is greater than or equal to about 1.5 and less than or equal to about 1.7.

11. The display device of claim 1, wherein a porosity of the first color conversion layer, a porosity of the second color conversion layer, and a porosity of the transmitting layer are different from one another.

12. A display device, comprising:
an emission panel comprising a plurality of light-emitting diodes;
a color panel disposed on the emission panel and comprising a first center area, a second center area, and a third center area respectively overlapping the plurality of light-emitting diodes and that emit light having different colors, wherein
the color panel comprises a function layer comprising:
a first color conversion layer corresponding to the first center area;
a second color conversion layer corresponding to the second center area; and
a transmitting layer corresponding to the third center area,
the first color conversion layer comprises first quantum dots;
the second color conversion layer comprises second quantum dots, and
each of the first color conversion layer, the second color conversion layer, and the transmitting layer comprises a base resin in which a plurality of pores are defined.

13. The display device of claim 12, wherein a size of each of the plurality of pores is greater than a size of each of the first quantum dots and a size of each of the second quantum dots.

14. The display device of claim 12, wherein each of the first color conversion layer, the second color conversion layer, and the transmitting layer comprises scattering particles and low-refractive objects having a refractive index greater than about 1.0 and less than or equal to about 1.3.

15. A method of manufacturing a display device, the method comprising:
preparing, on a substrate, a bank layer in which a first opening, a second opening, and a third opening are defined;
providing, in the first opening, a first material obtained by mixing a first base resin, porogen, and first quantum dots;
providing, in the second opening, a second material obtained by mixing a second base resin, porogen, and second quantum dots;
providing, in the third opening, a third material obtained by mixing a third base resin and porogen; and
forming, by heating the first material, the second material, and the third material, a function layer comprising a first color conversion layer, a second color conversion layer, and a transmitting layer each comprising a base resin in which a plurality of pores are defined.

16. The method of claim 15, wherein
a size of the plurality of pores is greater than a size of each of the first quantum dots, and
the size of the plurality of pores is greater than a size of each of the second quantum dots.

17. The method of claim 15, wherein the first material, the second material, and the third material each further comprises low-refractive objects having a refractive index greater than about 1.0 and less than or equal to about 1.3.

18. The method of claim 15, wherein content ratios of porogen in the first material, the second material, and the third material are different from one another.

19. The method of claim 15, wherein a refractive index of the function layer is greater than or equal to about 1.4 and less than or equal to about 1.7.

20. The method of claim 15, further comprising, before the forming of the bank layer:
forming, on the substrate, a color filter layer comprising a first color filter, a second color filter, and a third color filter; and
forming, on the color filter layer, a low-refractive layer having a refractive index less than a refractive index of the first color filter.
